(19) United States
(12) Patent Application Publication
(10) Pub. No.: US 2014/0338600 A1
(43) Pub. Date: Nov. 20, 2014

(54) EXHAUSTING APPARATUSES AND FILM DEPOSITION FACILITIES INCLUDING THE SAME

(71) Applicant: SAMSUNG ELECTRONICS CO., LTD., Suwon-si (KR)

(72) Inventors: Jong-Cheol LEE, Seoul (KR); Beom-Seok KIM, Seoul (KR); Suk-JIn CHUNG, Hwaseong-si (KR); Geun-Kyu CHOI, Hwaseong-si (KR)

(73) Assignee: SAMSUNG ELECTRONICS CO., LTD., Suwon-si (KR)

(21) Appl. No.: 14/259,433

(22) Filed: Apr. 23, 2014

(30) Foreign Application Priority Data
May 20, 2013 (KR) 10-2013-0056612

(51) Int. Cl. C23C 16/44

(52) U.S. Cl. CPC C23C 16/4412
USPC 118/722; 422/168; 423/210; 96/108; 96/110; 96/142; 95/90

(57) ABSTRACT

An exhausting apparatus includes an exhaust pump configured to extract unreacted precursor in a process chamber and vent the unreacted precursor out of the exhaust pump, and a first material supplier configured to supply a first material into the exhaust pump. The first material is adsorbable on an interior surface of the exhaust pump to prevent the unreacted precursor from being adsorbed on the interior surface of the exhaust pump.

### CROSS-REFERENCE TO RELATED APPLICATION

Korean Patent Application No. 10-2013-0056612, filed on May 20, 2013, in the Korean Intellectual Property Office, and entitled: “Exhausting Apparatuses and Film Deposition Facilities Including The Same,” is incorporated by reference herein in its entirety.

### BACKGROUND

Embodiments relate to an apparatus for fabricating semiconductor devices, and more particularly, to an exhausting apparatus and film deposition facility including the same.

### SUMMARY

Embodiments are directed to an exhausting apparatus including an exhaust pump configured to extract unreacted precursor in a process chamber and vent the unreacted precursor out of the exhaust pump, and a first material supplier configured to supply a first material into the exhaust pump. The first material is adsorbable on an interior surface of the exhaust pump to prevent the unreacted precursor from being adsorbed on the interior surface of the exhaust pump.

The first material may include at least one alcohol-type material.

The first material supplier may supply the first material into the exhaust pump before the exhaust pump extracts the unreacted precursor in the process chamber to vent the unreacted precursor out of the exhaust pump.

The first material supplier may be connected to an exhaust line that connects the process chamber to the exhaust pump.

The first material supplier may be directly connected to the exhaust pump.

The first material supplier may include a storage tank configured to store the first material, and a supply controller configured to control a flow rate and a supply time of the first material that is supplied from the storage tank into the exhaust pump.

The exhausting apparatus may further include a scrubber configured to be connected to the exhaust pump to remove the unreacted precursor vented out of the exhaust pump.

The exhausting apparatus may further include a second material supplier configured to supply a second material into the exhaust pump. The second material may be reactable with the unreacted precursor to form a product that is ventable without adsorption onto the interior surface of the exhaust pump.

The second material supplier may supply the second material into the exhaust pump before the exhaust pump extracts the unreacted precursor in the process chamber to vent the unreacted precursor out of the exhaust pump.

The unreacted precursor may include at least one of an organic compound material, an inorganic compound material, and an organo-metallic compound material.

Embodiments are also directed to a film deposition facility including a process chamber configured to perform a deposition process to deposit a film on a substrate using a precursor, an exhaust pump configured to extract unreacted precursor of the precursor in the process chamber to vent the unreacted precursor out of the exhaust pump, and a first material supplier configured to supply a first material into the exhaust pump. The first material is adsorbable on an interior surface of the exhaust pump to prevent the unreacted precursor from being adsorbed on the interior surface of the exhaust pump.

The first material supplier may supply the first material into the exhaust pump before the unreacted precursor is extracted from the process chamber and is introduced into the exhaust pump.

The film deposition facility may further include a second material supplier configured to supply a second material into the exhaust pump. The second material may be reactable with the unreacted precursor to faun a product that is ventable without adsorption onto the interior surface of the exhaust pump.

The film deposition facility may further include at least one trap installed at an exhaust line connecting the process chamber to the exhaust pump to remove the unreacted precursor.

The process chamber may provide a space in which a chemical vapor deposition (CVD) process or an atomic layer deposition (ALD) process is performed.

Embodiments are also directed to a method of exhausting a process chamber, the method including adsorbing a first material on an interior surface of an exhaust pump that extracts unreacted precursor from a process chamber and vents the unreacted precursor out of the exhaust pump, and after adsorbing the first material on the interior surface of the exhaust pump, operating the exhaust pump to extract the unreacted precursor from the process chamber and to vent the unreacted precursor out of the exhaust pump, the first material preventing the unreacted precursor from being adsorbed on the interior surface of the exhaust pump.

The first material may include at least one alcohol-type material.

The method may further include, after or during adsorbing the first material on the interior surface of the exhaust pump and before or during operating the exhaust pump to extract the unreacted precursor, supplying a second material to the exhaust pump, the second material being a material that is reactable with the unreacted precursor to form a product that is not adsorbable onto the interior surface of the exhaust pump.

### BRIEF DESCRIPTION OF THE DRAWINGS

Features will become apparent to those of skill in the art by describing in detail exemplary embodiments with reference to the attached drawings in which:

FIG. 1 illustrates a schematic view depicting a portion of an exhausting apparatus according to an embodiments;

FIG. 2 illustrates a flowchart depicting a method of venting materials contained in the exhausting apparatus illustrated in FIG. 1;

FIG. 3 illustrates a schematic view depicting a first material supplier of the exhausting apparatus illustrated in FIG. 1;

FIG. 4A illustrates a schematic diagram depicting a mechanism in which a film is deposited in an exhaust pump of a general exhausting apparatus;

FIG. 4B illustrates a schematic diagram depicting a mechanism in which deposition of a film is suppressed in an exhaust pump of the exhausting apparatus illustrated in FIG. 1;

FIG. 5 illustrates a histogram depicting deposition rates of the films shown in FIGS. 4A and 4B;

FIG. 6 illustrates a schematic view depicting a portion of another exhausting apparatus according to an embodiment;

FIG. 7 illustrates a flowchart depicting a method of venting materials contained in the exhausting apparatus illustrated in FIG. 6;

FIG. 8 illustrates a schematic diagram depicting a mechanism in which deposition of a film is suppressed in an exhaust pump of the exhausting apparatus illustrated in FIG. 6;

FIG. 9 illustrates a schematic view depicting a modification of the exhausting apparatus illustrated in FIG. 6;

FIG. 10 illustrates a schematic view illustrating a portion of another exhausting apparatus according to an embodiment;

FIG. 11 illustrates a schematic view depicting a portion of another exhausting apparatus according to an embodiment;

FIG. 12 illustrates a schematic view depicting a portion of a film deposition facility according to an embodiment;

FIG. 13 illustrates a schematic view depicting a portion of another film deposition facility according to an embodiment;

FIG. 14 illustrates a schematic view depicting a portion of another film deposition facility according to an embodiment; and

FIG. 15 illustrates a schematic view depicting a portion of yet another film deposition facility according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

Although the teams “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer, or section discussed below could be termed a second element, component, region, layer or section without departing from the teachings of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Expressions such as “at least one of,” when preceding a list of elements, modify the entire list of elements and do not modify the individual elements of the list.

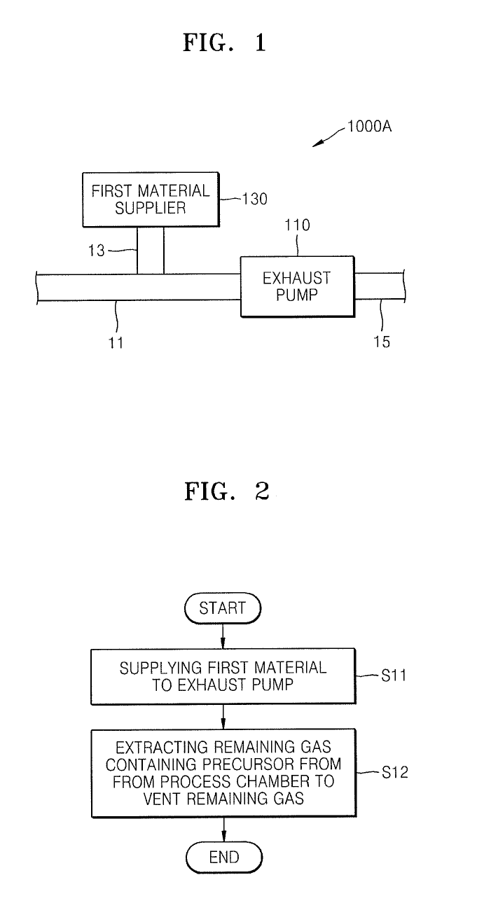

FIG. 1 illustrates a schematic view depicting a portion of an exhausting apparatus 1000A according to an embodiment. FIG. 2 illustrates a flowchart depicting a method of venting materials contained in the exhausting apparatus 1000A illustrated in FIG. 1.

Referring to FIG. 1, the exhausting apparatus 1000A may include an exhaust pump 110 and a first material supplier 130.

The exhaust pump 110 may be connected to a process chamber through a first exhaust line 11. The process chamber may provide a closed space in which a film deposition process is performed to form a thin film on a surface of a substrate. The exhaust pump 110 may extract a remaining gas in the process chamber through the first exhaust line 11 during the film deposition process, for example, by sucking in the remaining gas. The remaining gas introduced into the exhaust pump 110 may then be vented out of the exhaust pump 110 through a third exhaust line 15. The remaining gas may include a gaseous precursor that does not participate in a chemical reaction for depositing a film. The gaseous precursor may include at least one selected from the group of an organic compound material, an inorganic compound material, and an organo-metallic compound material. In some embodiments, the precursor may include at least one selected from the group of lithium (Li), beryllium (Be), boron (B), sodium (Na), magnesium (Mg), aluminum (Al), potassium (K), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), rubidium (Rb), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), antimony (Sb), cesium (Cs), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), iridium (Ir), platinum (Pt), gold (Au), mercury (Hg), lead (Pb), bismuth (Bi), polonium (Po), francium (Fr), radium (Ra), actinium (Ac), and silicon (Si). The remaining gas may further include at least one of a reaction gas, a byproduct generated by a chemical reaction in the process chamber, a carrier gas, and a cleaning gas.

The exhaust pump 110 may be configured to include a turbo-molecular pump or a dry pump to obtain a high vacuum range in the process chamber. In other implementations, the exhaust pump 110 may include a rotary pump or the like to obtain an ultrahigh vacuum range in the process chamber.

The first material supplier 130 may be connected to the first exhaust line 11 through a second exhaust line 13. The first material supplier 130 may supply a first material to the exhaust pump 110 through the first and second exhaust lines 11 and 13.

The first material may suppress an adsorption of the precursor contained in the remaining gas on interior surfaces of the exhaust pump 110. In some implementations, the first material may include at least one alcohol-type material. For example, the first material may include at least one of methanol (MeOH), ethanol (EtOH), t-butanol (t-BuOH), isopropyl alcohol (IPA), and phenol (PeOH).

Referring to FIG. 2, the exhausting apparatus 1000A may supply the first material to the exhaust pump 110 (S 11). Thereafter, the exhausting apparatus 1000A may extract the remaining gas from the process chamber to vent the remaining gas out of the exhausting apparatus 1000A (S12).

Before the exhaust pump 110 extracts the remaining gas from the process chamber to vent the remaining gas out of the exhausting apparatus 1000A, the first material supplier 130 may supply the first material into the exhaust pump 110 through the first and second exhaust lines 11 and 13 such that the first material is adsorbed on the interior surfaces of the exhaust pump 110. Subsequently, the exhausting apparatus 1000A may operate such that the exhaust pump 110 extracts the remaining gas from the process chamber and vents the remaining gas out of the exhausting apparatus 1000A through the third exhaust line 15.

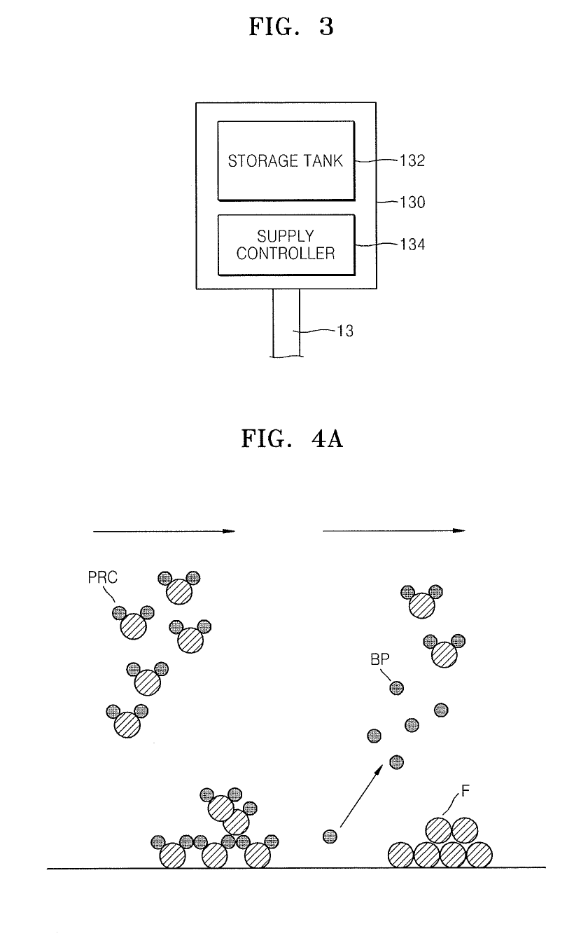

As described above, the exhausting apparatus 1000A may introduce the first material into the exhaust pump 110 to adsorb the first material onto the interior surfaces of the exhaust pump 110 and may then vent the remaining gas in the process chamber out of the exhausting apparatus 1000A using the exhaust pump 110. The first material coated on the interior surfaces of the exhaust pump 110 may prevent the precursor contained in the remaining gas from being adsorbed on the interior surfaces of the exhaust pump 110. As a result, the exhausting apparatus 1000A may suppress a deposition of a thin film on the interior surfaces of the exhaust pump 110 when the remaining gas is vented through the exhaust pump 110. Hereinafter, a mechanism in which deposition of the precursor is suppressed inside the exhaust pump 110 will be described more fully with reference to FIGS. 3, 4A, 4B, and 5.

FIG. 3 illustrates a schematic view depicting the first material supplier 130 of the exhausting apparatus 1000A shown in FIG. 1.

Referring to FIG. 3, the first material supplier 130 may include a storage tank 132 and a supply controller 134.

The storage tank 312 may store the first material therein. In some implementations, the storage tank 132 may be configured to include at least one canister that stores the first material in a gas state or a liquid state.

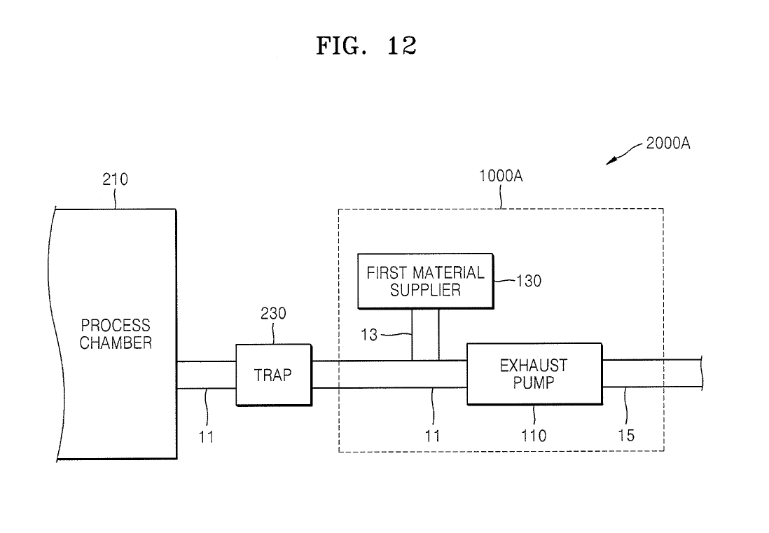

The supply controller 134 may determine whether the first material is to be supplied to the exhaust pump 110. In addition, the supply controller 134 may control the supply time of the first material and/or the supply amount of the first material. The supply controller 134 may be controlled by a main controller that controls overall operations of components constituting a facility (e.g., a film deposition facility 2000A of FIG. 12) to which the exhausting apparatus 1000A is connected and that controls flow rates of source gases injected into the process chamber of the facility. The main controller may control the supply controller 134 such that the supply controller 134 supplies the first material to the exhaust pump 110 during a time period that is different from a time period in which the exhaust pump 110 extracts the remaining gas from the process chamber. Further, the main controller may control the supply controller 134 such that the supply controller 134 changes the flow rate of the first material while the first material is supplied to the exhaust pump 110.

The supply controller 134 may include structure that controls the opening/closing of the storage tank 132, such as, for example, a valve, and the second exhaust line 13. In some implementations, the supply controller 134 may further include a heater that heats the first material to a predetermined temperature to provide the exhaust pump 110 with the heated first material.

The supply controller 134 may be connected to the second exhaust line 13 and may also be connected to the storage tank 132 through a conduit line (not shown). In other implementations, the supply controller 134 and the storage tank 132 may be unified without use of any conduit lines there between, and the unified first material supplier 130 may also control various process parameters relating to the first material.

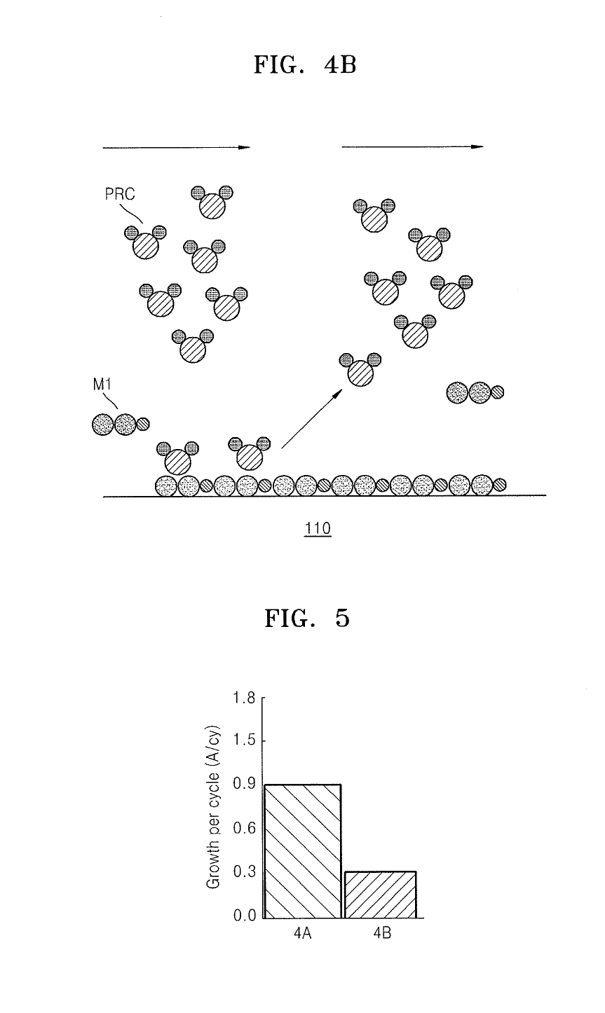

Without being bound to any particular theory FIG. 4A illustrates a schematic diagram depicting a possible mechanism in which a film is deposited in an exhaust pump of a general exhausting apparatus, and FIG. 4B illustrates a schematic diagram illustrating a possible mechanism in which deposition of a film is suppressed in the exhaust pump 110 of the exhausting apparatus 1000A shown in FIG. 1. In addition, FIG. 5 illustrates a histogram illustrating deposition rates of the films shown in FIGS. 4A and 4B. In the fabrication of the experimental samples exhibiting the data of FIG. 5, a Zr-amide type compound material was used as the precursor to form a zirconium oxide (ZrO₂) film, and a methanol (MeOH) material was used as the first material. Further, in each of FIGS. 4A and 4B, only the precursor is representatively illustrated as the remaining gas introduced into the exhaust pump.

Referring to FIG. 4A, if the precursors PRC that do not participate in a chemical reaction in the process chamber of the general exhausting apparatus are introduced into the exhaust pump, a portion of the precursors PRC may be chemically and/or physically adsorbed onto an interior surface of the exhaust pump. The precursors PRC adsorbed on the interior surface of the exhaust pump may form a film F through a surface reaction, a surface diffusion, and/or a crystal lattice formation that may occur due to heat generated by operation of the exhaust pump or due to reaction gases (not shown) introduced into the exhaust pump. Subsequently, a byproduct BP generated by a chemical reaction in the exhaust pump is desorbed from the interior surface of the exhaust pump, and the desorbed byproduct BP and the unadsorbed precursors PRC are vented out of the exhaust pump.

Referring to FIGS. 1 and 4B, in the exhausting apparatus 1000A according to embodiments, the first material M1 is introduced into the exhaust pump 110 and is adsorbed onto the interior surface of the exhaust pump 110 before the precursors PRC that do not participate in a chemical reaction in the process chamber of the exhausting apparatus 1000A are introduced into the exhaust pump 110. Thus, the first material M1 coated on the interior surface of the exhaust pump 110 may prevent the precursors PRC from being adsorbed onto the interior surface of the exhaust pump 110. As a result, even though heat is generated by operation of the exhaust pump 110 or reaction gases are introduced into the exhaust pump 110, the first material M1 on the interior surface of the exhaust pump 110 may prevent the precursors PRC from reacting with the interior surface of the exhaust pump 110. Thus, the formation of additional films on the interior surface of the exhaust pump 110 may be prevented or minimized, as illustrated in FIG. 4B.

Referring to FIG. 5, a growth rate (or a deposition rate) of the zirconium oxide (ZrO₂) layer formed on the interior surface of the exhaust pump 110 of the exhausting apparatus 1000A according to embodiments is lower than a growth rate (or a deposition rate) of the ZrO₂ layer formed on the interior surface of the exhaust pump of the general exhausting apparatus.

As described above, the exhausting apparatus 1000A according to embodiments may suppress the formation of a precursor film on the interior surfaces of the components of the exhaust pump 110 while the remaining gas in the process chamber is vented by the exhaust pump 110. Thus, a reduction of clearances between the components of the vacuum pump 110 and damage to the components of the exhaust pump 110 may be prevented or minimized. As a result, the endurance of the exhaust pump 110 may be improved to prevent a malfunction of the exhaust pump 110. Accordingly, an abnormal deposition of a desired film in the process chamber may be prevented or minimized. Further, the exhaust pump 110 may be independently and periodically cleaned to reduce the maintenance cost of the exhausting apparatus 1000A.

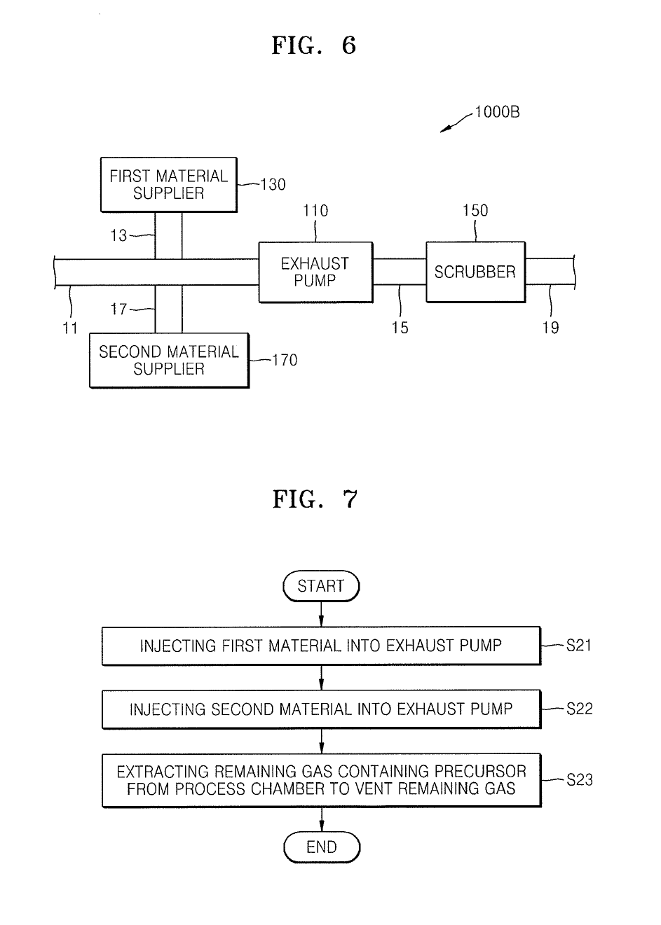

FIG. 6 illustrates a schematic view depicting a portion of an exhausting apparatus 1000B according to another embodiment, and FIG. 7 illustrates a flowchart depicting a method of venting materials contained in the exhausting apparatus 1000B shown in FIG. 6. In FIG. 6, the same reference numerals as used in FIG. 1 denote the same elements. Thus, detailed descriptions of the same elements as set forth with reference to FIG. 1 are not repeated.

Referring to FIG. 6, the exhausting apparatus 1000B may include the exhaust pump 110, the first material supplier 130, a scrubber 150, and a second material supplier 170.

The scrubber 150 may be connected to the exhaust pump 110 through the third exhaust line 15. The scrubber 150 may purify the remaining gas vented from the exhaust pump 110. Specifically, the scrubber 150 may remove the precursors contained in the remaining gas or reaction materials generated by reaction of the precursors and the reaction gas (e.g., a silane (SiH₄) gas, an ammonia (NH₃) gas, a phosphine (PH₃) gas, or a hydrogen (H₂) gas to purify the remaining gas. As a result, the scrubber 150 may prevent the precursors and the reaction materials from being stagnated or solidified inside the third exhaust line 15 to degrade the performance of the exhaust pump 110. The scrubber 150 may vent the purified gas of the remaining gas through a fifth exhaust line 19.

In some implementations, the scrubber 150 may be configured to include a dry scrubber, a wet scrubber, or a combination thereof.

The second material supplier 170 may be connected to the first exhaust line 11 through a fourth exhaust line 17. The second material supplier 170 may supply a second material to the exhaust pump 110 through the first and fourth exhaust lines 11 and 17. The second material may remove the precursors by reacting with the precursors to form predetermined products. In some implementations, the second material may include at least one halogen material. In such a case, the precursors and the halogen material may react to generate a halide material that is not adsorbed on the interior surface of the exhaust pump 110. The halide material may be vented out of the exhaust pump 110. In some implementations, the second material may include at least one of a chlorine (Cl₂) gas, a bromine (Br) gas, and an iodine (I) gas. The second material supplier 170 may further include a plasma treatment unit (not shown) that changes the second material into a radical form. In addition, the second material supplier 170 may further include a reaction chamber that is disposed between the process chamber and the exhaust pump 110 to provide a reaction space in which the second material and the precursors react with each other.

Referring to FIG. 7, the exhausting apparatus 1000B may supply the first material into the exhaust pump 110 (S21). The exhausting apparatus 1000B may supply the second material into the exhaust pump 110 (S22). Subsequently, the exhausting apparatus 1000B may extract the remaining gas from the process chamber to vent the remaining gas out of the exhausting apparatus 1000B (S23).

Before the exhaust pump 110 extracts the remaining gas from the process chamber to vent the remaining gas out of the exhausting apparatus 1000B, the first material supplier 130 may supply the first material into the exhaust pump 110 through the first and second exhaust lines 11 and 13 such that the first material is adsorbed on the interior surfaces of the exhaust pump 110. The second material supplier 170 may supply the second material into the exhaust pump 110 through the first and fourth exhaust lines 11 and 17 such that the second material is present inside the exhaust pump 110. Subsequently, the exhausting apparatus 1000B may operate such that the exhaust pump 110 extracts the remaining gas from the process chamber and vents the remaining gas out of the exhausting apparatus 1000B through the third exhaust line 15, the scrubber 150, and the fifth exhaust line 19.

As described above, after the first material is adsorbed on the interior surface of the exhaust pump 110, the second material and the remaining gas may be sequentially introduced into the exhaust pump 110. The precursors contained in the remaining gas may react with the second material to generate a byproduct, and the byproduct, including the precursors, may be vented and removed from the exhaust pump 110. The amount of the precursors may be significantly reduced in the exhaust pump 110 to prevent a film from being adsorbed and formed on the interior surface of the exhaust pump 110. Hereinafter, a mechanism in which deposition of the precursors is suppressed in the exhaust pump 110 will be described more fully with reference to FIG. 8.

Without being bound to any particular theory, FIG. 8 illustrates a schematic diagram depicting a possible mechanism in which deposition of the precursors is suppressed inside the exhaust pump 110 of the exhausting apparatus 1000B shown in FIG. 6. In FIG. 8, the same reference numerals as used in FIGS. 4A and 4B denote the same elements. Thus, detailed descriptions of the same elements as set forth with reference to FIGS. 4A and 4B are not repeated.

Referring to FIGS. 6 and 8, in the exhausting apparatus 1000B according to embodiments, the first material M1 may be introduced into the exhaust pump 110 and adsorbed onto the interior surface of the exhaust pump 110 before the precursors PRC that have not participated in a chemical reaction in the process chamber of the exhausting apparatus 1000B are introduced into the exhaust pump 110. Further, before the precursors PRC are introduced into the exhaust pump 110, the second material M2 may be supplied into the exhaust pump 110 after the first material M1 is introduced into the exhaust pump 110.

A portion of the precursors PRC may react with the second material M2 to generate products P that are not adsorbed on the interior surface of the exhaust pump 110. The number of precursors PRC in the exhaust pump 110 may be significantly reduced. The first material M1 coated on the interior surface of the exhaust pump 110 may prevent the precursors PRC from being adsorbed on the interior surface of the exhaust pump 110. Even though heat is generated by operation of the exhaust pump 110 or reaction gases are introduced into the exhaust pump 110, formation of the film F illustrated in FIG. 4A on the interior surface of the exhaust pump 110 may be prevented or minimized because of lack of the precursors PRC acting as a source material of the film F and poor surface reaction of the precursors PRC due to the presence of the first material M1 coated on the interior surface of the exhaust pump 110.

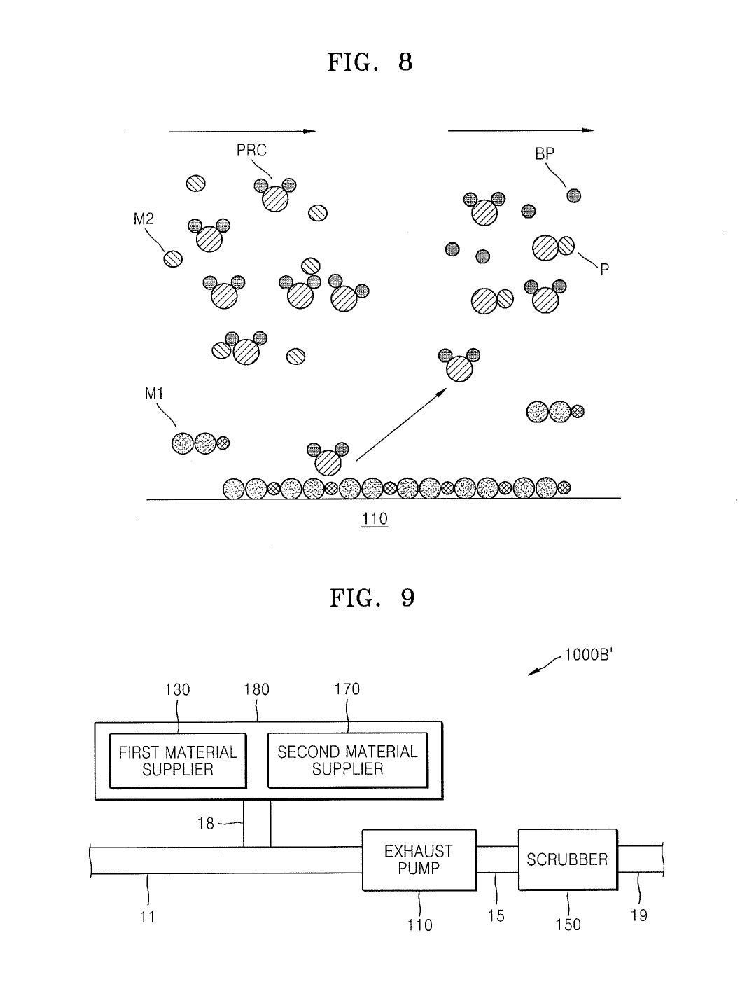

FIG. 9 illustrates a schematic view depicting an exhausting apparatus 1000B′ according to a modification of the exhausting apparatus 1000B shown in FIG. 6. In FIG. 9, the same reference numerals as used in FIGS. 1 and 6 denote the same elements. Thus, detailed descriptions of the same elements as set forth with reference to FIGS. 1 and 6 will not be repeated, and differences between the present embodiment and the previous embodiments will be mainly described in detail hereinafter.

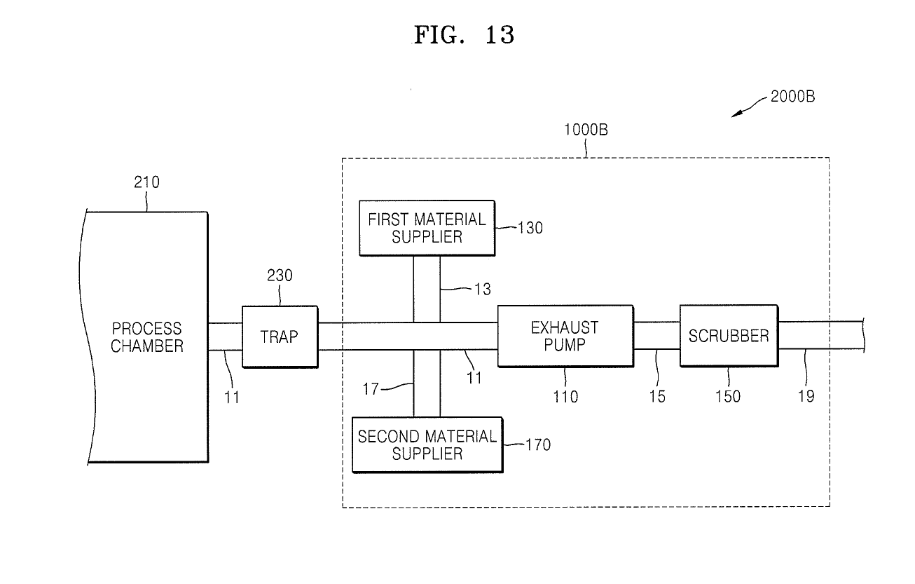

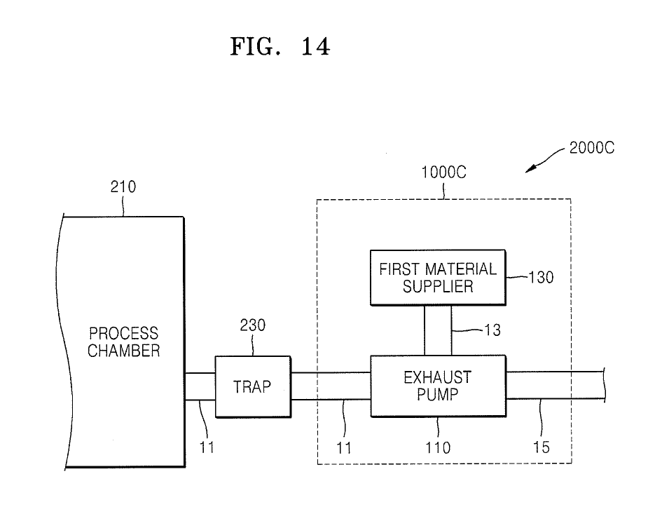

Referring to FIG. 9, the first material supplier 130 and the second material supplier 170 may be unified to constitute a single anti-deposition material supplier 180. That is, the first and second material suppliers 130 and 170 constituting the anti-deposition material supplier 180 may share a sixth exhaust line 18, and the anti-deposition material supplier 180 may be connected to the first exhaust line 11 through the sixth exhaust line 18. In some implementations, the first and second material suppliers 130 and 170 may be controlled by a single controller (not shown) disposed in the anti-deposition material supplier 180. In other implementations, the first and second material suppliers 130 and 170 may be controlled by a main controller (not shown) that controls overall operations of components constituting a facility (e.g., a film deposition facility 2000B of FIG. 13) to which the exhausting apparatus 1000B′ is connected. The first and second material suppliers 130 and 170 may be unified to constitute the single anti-deposition material supplier 180. Accordingly, a size of the exhausting apparatus 1000B′ may be reduced. As a result, the exhausting apparatus 1000B′ may be efficiently installed and disposed in a limited space.

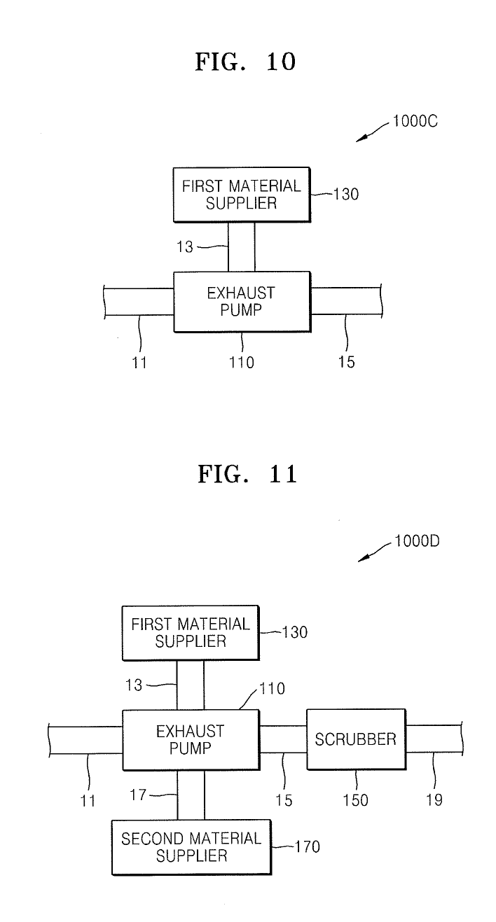

FIG. 10 illustrates a schematic view depicting a portion of an exhausting apparatus 1000C according to another embodiment, and FIG. 11 illustrates a schematic view depicting a portion of an exhausting apparatus 1000D according to yet another embodiment. In FIGS. 10 and 11, the same reference numerals as used in FIGS. 1 and 6 denote the same elements. Thus, detailed descriptions of the same elements as set forth with reference to FIGS. 1 and 6 are not repeated, and differences between the present embodiment and the previous embodiments will be mainly described in detail hereinafter.

Referring to FIG. 10, the exhausting apparatus 1000C may include the exhaust pump 110 and the first material supplier 130. The exhausting apparatus 1000C may have a configuration in which the exhaust pump 110 and the first material supplier 130 are directly connected to each other through the second exhaust line 13. According to the exhausting apparatus 1000C, the exhaust pump 110 may be directly connected to the first material supplier 130 such that a path through which the first material is supplied may have a minimum length. Accordingly, the first material may be efficiently and effectively adsorbed on the interior surface of the exhaust pump 110.

Referring to FIG. 11, the exhausting apparatus 1000D may include the exhaust pump 110, the first material supplier 130, the scrubber 150, and the second material supplier 170. The exhausting apparatus 1000D may have a configuration in which the exhaust pump 110 and the first material supplier 130 are directly connected to each other through the second exhaust line 13, and the exhaust pump 110 and the second material supplier 170 are directly connected to each other through the fourth exhaust line 17. As in the embodiment illustrated in FIG. 10, the first material supplier 130 may be directly connected to the exhaust pump 110. The first material may be efficiently and effectively adsorbed on the interior surface of the exhaust pump 110. Further, the second material supplier 170 may be directly connected to the exhaust pump 110 such that a length of a path through which the second material is supplied to suppress the reaction between the elements in the second material may be minimized. As a result, the precursors introduced into the exhaust pump 110 may be efficiently removed.

Although FIG. 11 illustrates the exhausting apparatus 1000D having a configuration where each of the first and second material suppliers 130 and 170 is directly connected to the exhaust pump 110, in other embodiments, the exhausting apparatus 1000D may be modified to have a configuration in which the first material supplier 130 is connected to the first exhaust line 11 through the second exhaust line 13 as illustrated in FIG. 1, and the second material supplier 170 is connected to the exhaust pump 110 through the fourth exhaust line 17. In other embodiments, the exhausting apparatus 1000D may be modified to have a configuration in which the second material supplier 170 is connected to the first exhaust line 11 through the fourth exhaust line 17 as illustrated in FIG. 6, and the first material supplier 130 is connected to the exhaust pump 110 through the second exhaust line 13. In still other embodiments, the exhausting apparatus 1000D may be modified to have a configuration in which the first and second material suppliers 130 and 170 are unified to constitute the single anti-deposition material supplier 180 as illustrated in FIG. 9 and the anti-deposition material supplier 180 is directly connected to the exhaust pump 110 through the sixth exhaust line 18.

FIG. 12 illustrates a schematic view depicting a portion of a film deposition facility 2000A according to an embodiment. In FIG. 12, the same reference numerals as used in FIG. 1 denote the same elements. Thus, detailed descriptions of the same elements as set forth with reference to FIG. 1 are not repeated, and differences between the present embodiment and the previous embodiments will be mainly described in detail hereinafter.

Referring to FIG. 12, the film deposition facility 2000A may include a process chamber 210, a trap 230, and the exhausting apparatus 1000A. The exhausting apparatus 1000A may include the exhaust pump 110 and the first material supplier 130, as described with reference to FIG. 1.

The process chamber 210 may provide a sealed space in which a film deposition process is performed. In some embodiments, a chemical vapor deposition (CVD) process may be performed in the process chamber 210. The CVD process may be any one of a thermal CVD process, a plasma CVD process, a photo CVD process and a laser CVD process according to an energy source used therein. Further, the CVD process may be either an atmospheric pressure chemical vapor deposition (APCVD) process or a low pressure chemical vapor deposition (LPCVD) process according to a deposition pressure. Moreover, the CVD process may be either a metal organic chemical vapor deposition (MOCVD) process or a metal inorganic chemical vapor deposition (MICVD) process according to a reaction material. In other implementations, for example, other processes, such as an atomic layer deposition (ALD) process, may be performed in the process chamber 210. The process chamber 210 may be configured to receive a gaseous precursor and an oxidizer from a gas supplier (not shown) and to include a heater to decompose the precursor and a handler to manipulate a substrate.

The exhaust pump 110 may be connected to the process chamber 210 through the first exhaust line 11. The exhaust pump 110 may extract the remaining gas in the process chamber 210 and may suck the remaining gas through the first exhaust line 11. Further, the exhaust pump 110 may vent the remaining gas out of the film deposition facility 2000A through the third exhaust line 15.

The first material supplier 130 may be connected to the first exhaust line 11 through the second exhaust line 13. The first material supplier 130 may supply the first material to the exhaust pump 110 through the first and second exhaust lines 11 and 13. The first material supplier 130 may supply the first material to the exhaust pump 110 before the exhaust pump 110 extracts the remaining gas from the process chamber 210 to vent the remaining gas out of the film deposition facility 2000A. After the first material is adsorbed on the interior surface of the exhaust pump 110, the remaining gas may be introduced into the exhaust pump 110. This process may prevent or hinder the precursor contained in the remaining gas from being adsorbed on the interior surface of the exhaust pump 110.

As described above, the exhausting apparatus 2000A may suppress a formation of a precursor film on the interior surfaces of the components of the exhaust pump 110 during a period in which the remaining gas in the process chamber 210 is vented by the exhaust pump 110. Thus, endurance or longevity of the exhausting apparatus 2000A may be improved, and a malfunction of the exhaust pump 110 may be prevented or the likelihood thereof may be reduced. Accordingly, an abnormal deposition of a desired film in the process chamber 210 may be prevented or reduced. Further, the exhaust pump 110 may be independently and periodically cleaned to reduce the maintenance cost of the exhausting apparatus 1000A.

At least one trap 230 may be disposed at the first exhaust line 11. The trap 230 may remove or reduce the amount of the precursor in the remaining gas that has not participated in a chemical reaction in the process chamber 210. The trap 230 may be configured to include a cold trap, a hot disk trap, or a combination thereof. Although FIG. 12 illustrates the film deposition facility 2000A having a configuration where the trap 230 is disposed only at the first exhaust line 11, in other implementations, the trap 230 may be disposed at the second exhaust line 13 and/or the third exhaust line 15.

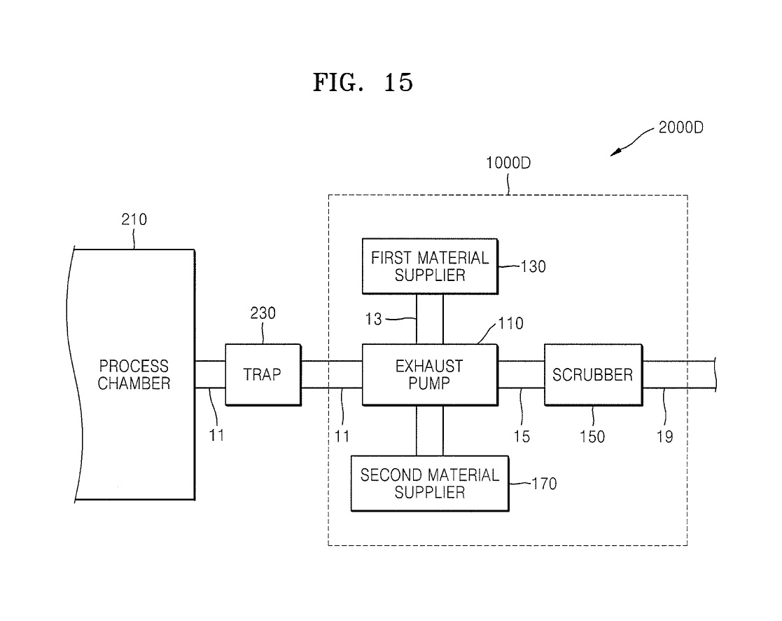

FIGS. 13, 14, and 15 illustrate schematic views depicting other film deposition facilities 2000B, 2000C, and 2000D according to other embodiments. The film deposition facility 2000B of FIG. 13 may be configured to include the process chamber 210 and the trap 230, as illustrated in FIG. 12, and the exhausting apparatus 1000B as illustrated in FIG. 6. The film deposition facility 2000C of FIG. 14 may be configured to include the process chamber 210 and the trap 230 as illustrated in FIG. 12, and the exhausting apparatus 1000C as illustrated in FIG. 10. The film deposition facility 2000D of FIG. 15 may be configured to include the process chamber 210 and the trap 230 as illustrated in FIG. 12 and the exhausting apparatus 1000D as illustrated in FIG. 11. Accordingly, detailed descriptions of the film deposition facilities 2000B, 2000C and 2000D will be not be repeated.

By way of summation and review, in a film deposition process used in fabrication of semiconductor devices with various materials, a gaseous material, for example, a precursor may be introduced into a process chamber to form a film. However, while only a small amount of the precursor is used in forming the film, most of the precursor is vented out of the process chamber with a byproduct. The precursor and the byproduct in the process chamber may be extracted by an exhaust pump, such as a vacuum pump, and may be introduced into the vacuum pump through an exhaust line. The precursor and the byproduct in the vacuum pump may then be exhausted out of the vacuum pump. In such a case, the precursor may decompose due to heat generated from the vacuum pump or due to a chemical reaction with process gases exhausted from the process chamber. The decomposed precursor may be readily deposited on surfaces of internal components of the vacuum pump to form a thin film. Thus, clearances between the components of the vacuum pump may be reduced to cause abrasion and damage of the components of the vacuum pump.

Conventional vacuum pumps have been typically cleaned periodically or replaced with new vacuum pumps, or the unreacted precursor has been intentionally oxidized to remove the unreacted precursor before the unreacted precursor is introduced into the vacuum pump. However, when vacuum pumps are cleaned periodically or replaced with new vacuum pumps, maintenance costs with respect to the vacuum pumps may be increased. Further, when the unreacted precursor is intentionally oxidized to remove the unreacted precursor, the efficiency of removing the unreacted precursor may be too low.

Embodiments provide an exhausting apparatus and film deposition facility in which deposition of precursors or byproducts remaining in a process chamber may be exhausted while preventing or reducing the likelihood of the precursors or byproducts being deposited on surfaces of internal components of the vacuum pump.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An exhausting apparatus, comprising:
an exhaust pump configured to extract unreacted precursor in a process chamber and vent the unreacted precursor out of the exhaust pump; and
a first material supplier configured to supply a first material into the exhaust pump,
wherein the first material is adsorbable on an interior surface of the exhaust pump to prevent the unreacted precursor from being adsorbed on the interior surface of the exhaust pump.

2. The exhausting apparatus as claimed in claim 1, wherein the first material includes at least one alcohol-type material.

3. The exhausting apparatus as claimed in claim 1, wherein the first material supplier supplies the first material into the exhaust pump before the exhaust pump extracts the unreacted precursor in the process chamber to vent the unreacted precursor out of the exhaust pump.

4. The exhausting apparatus as claimed in claim 1, wherein the first material supplier is connected to an exhaust line that connects the process chamber to the exhaust pump.

5. The exhausting apparatus as claimed in claim 1, wherein the first material supplier is directly connected to the exhaust pump.

6. The exhausting apparatus as claimed in claim 1, wherein the first material supplier includes:
a storage tank configured to store the first material; and
a supply controller configured to control a flow rate and a supply time of the first material that is supplied from the storage tank into the exhaust pump.

7. The exhausting apparatus as claimed in claim 1, further comprising a scrubber configured to be connected to the exhaust pump to remove the unreacted precursor vented out of the exhaust pump.

8. The exhausting apparatus as claimed in claim 1, further comprising a second material supplier configured to supply a second material into the exhaust pump,
wherein the second material is reactable with the unreacted precursor to form a product that is ventable without adsorption onto the interior surface of the exhaust pump.

9. The exhausting apparatus as claimed in claim 8, wherein the second material supplier supplies the second material into the exhaust pump before the exhaust pump extracts the unreacted precursor in the process chamber to vent the unreacted precursor out of the exhaust pump.

10. The exhausting apparatus as claimed in claim 1, wherein the unreacted precursor includes at least one of an organic compound material, an inorganic compound material, and an organo-metallic compound material.

11. A film deposition facility, comprising:
a process chamber configured to perform a deposition process to deposit a film on a substrate using a precursor;
an exhaust pump configured to extract unreacted precursor of the precursor in the process chamber to vent the unreacted precursor out of the exhaust pump; and
a first material supplier configured to supply a first material into the exhaust pump,
wherein the first material is adsorbable on an interior surface of the exhaust pump to prevent the unreacted precursor from being adsorbed on the interior surface of the exhaust pump.

12. The film deposition facility as claimed in claim 11, wherein the first material supplier supplies the first material into the exhaust pump before the unreacted precursor is extracted from the process chamber and is introduced into the exhaust pump.

13. The film deposition facility as claimed in claim 11, further comprising a second material supplier configured to supply a second material into the exhaust pump,
wherein the second material is reactable with the unreacted precursor to form a product that is ventable without adsorption onto the interior surface of the exhaust pump.

14. The film deposition facility as claimed in claim 11, further comprising at least one trap installed at an exhaust line connecting the process chamber to the exhaust pump to remove the unreacted precursor.

15. The film deposition facility as claimed in claim 11, wherein the process chamber provides a space in which a chemical vapor deposition (CVD) process or an atomic layer deposition (ALD) process is performed.

16. A method of exhausting a process chamber, the method comprising:
adsorbing a first material on an interior surface of an exhaust pump that extracts unreacted precursor from a process chamber and vents the unreacted precursor out of the exhaust pump; and
after adsorbing the first material on the interior surface of the exhaust pump, operating the exhaust pump to extract the unreacted precursor from the process chamber and to vent the unreacted precursor out of the exhaust pump, the first material preventing the unreacted precursor from being adsorbed on the interior surface of the exhaust pump.

17. The method as claimed in claim 16, wherein the first material includes at least one alcohol-type material.

18. The method as claimed in claim 16, further including, after or during adsorbing the first material on the interior surface of the exhaust pump and before or during operating the exhaust pump to extract the unreacted precursor, supplying a second material to the exhaust pump, the second material being a material that is reactable with the unreacted precursor to form a product that is not adsorbable onto the interior surface of the exhaust pump.
